(19) United States
(12) Patent Application Publication
(10) Pub. No.: US 2011/0158001 A1
(43) Pub. Date: Jun. 30, 2011

(54) PROGRAMMING METHOD FOR NONVOLATILE MEMORY DEVICE

(75) Inventor: Byoung In JOO, Seoul (KR)

(73) Assignee: HYNIX SEMICONDUCTOR INC., Icheon-si (KR)

(21) Appl. No.: 12/982,794

(22) Filed: Dec. 30, 2010

(30) Foreign Application Priority Data
Dec. 31, 2009 (KR) 10-2009-0135621

(51) Int. Cl. G11C 16/10

(52) U.S. Cl. 365/185.22; 365/185.18; 365/185.24

(57) ABSTRACT

A programming method for a nonvolatile memory device includes inputting least significant bit (LSB) data and most significant bit (MSB) data to each of different latches of a page buffer and in the state in which the LSB data and the MSB data have been inputted to the page buffer, performing a programming operation until threshold voltages of selected memory cells reach a target voltage on the basis of the LSB data and the MSB data.

### CROSS-REFERENCE TO RELATED APPLICATION

Priority is claimed to Korean patent application number 10-2009-0135621 filed on Dec. 31, 2009, the entire disclosure of which is incorporated by reference herein.

### BACKGROUND

Exemplary embodiments relate to a programming method for a nonvolatile memory device and, more particularly, to a programming method of a nonvolatile memory device which is capable of reducing the time that it takes to perform a programming operation.

A nonvolatile memory device includes a memory cell array in which data is stored, a page buffer for program, erase, and read operations, and an I/O circuit unit for providing a data I/O path to the page buffer for the data I/O of the memory cell array. The memory cell array includes a plurality of memory cells coupled between word lines and bit lines. The page buffer includes a plurality of latches.

A programming operation is described below with reference to the construction of the nonvolatile memory device.

When a program command is received, least significant bit (hereinafter referred to as ‘LSB’) data is inputted to the latch of the page buffer. An LSB programming operation is performed on selected memory cells on the basis of the LSB data inputted to the latch. In the LSB programming operation, the selected memory cells are programmed until threshold voltages of the selected memory cells reach a temporary voltage lower than a target voltage. After the LSB programming operation is completed, a command for a most significant bit (hereinafter referred to as ‘MSB’) programming operation is received. MSB data is inputted to the latch of the page buffer. The MSB programming operation is performed on the selected memory cells on the basis of the MSB data inputted to the latch. The MSB programming operation is performed until threshold voltages of the selected memory cells reach the target voltage.

In the above programming operations, after the LSB data is inputted and the LSB programming operation is performed, the MSB data is inputted and the MSB programming operation is performed. Accordingly, the time that it takes to perform the entire programming operation is long.

### BRIEF SUMMARY

Exemplary embodiments relate to a programming method of a nonvolatile memory device, which is capable of reducing the time that it takes to perform the entire programming operation by performing LSB and MSB programming operations after both LSB data and MSB data are inputted to page buffers.

A programming method of a nonvolatile memory device according to an aspect of the present disclosure includes inputting least significant bit (LSB) data and most significant bit (MSB) data to different latches of a page buffer. When the LSB data and the MSB data have been inputted to the page buffer, a programming operation is performed until threshold voltages of selected memory cells reach a target voltage on the basis of the LSB data and the MSB data.

A programming method for a nonvolatile memory device according to another aspect of the present disclosure includes inputting MSB data to a first latch of a page buffer and LSB data to a second latch, performing an LSB programming operation on selected memory cells using the LSB data, and performing an MSB programming operation on the selected memory cells using the MSB data.

According to yet another aspect of the present disclosure, there is provided a programming method for a nonvolatile memory device comprising a page buffer including first and second latches. LSB data is inputted to the first latch, sending the LSB data of the first latch to the second latch, inputting MSB data to the first latch, performing an LSB programming operation until threshold voltages of selected memory cells reach a second target voltage using the LSB data of the second latch, and performing an MSB programming operation until threshold voltages of the selected memory cells reach a first target voltage or a third target voltage using the MSB data of the first latch.

### BRIEF DESCRIPTION OF THE DRAWINGS

FIG. 1 is a flowchart illustrating a programming method for a nonvolatile memory device according to an exemplary embodiment of this disclosure;

FIG. 2 is a schematic block diagram of a nonvolatile memory device illustrating the programming method according to this disclosure;

FIG. 3 is a diagram illustrating the states of memory cells according to threshold voltages; and

FIG. 4 is a block diagram illustrating a programming method of a nonvolatile memory device according to an exemplary embodiment of this disclosure.

### DESCRIPTION OF EMBODIMENTS

Hereinafter, some exemplary embodiments of the present disclosure will be described in detail with reference to the accompanying drawings. The figures are provided to allow those having ordinary skill in the art to understand the scope of the embodiments of the disclosure.

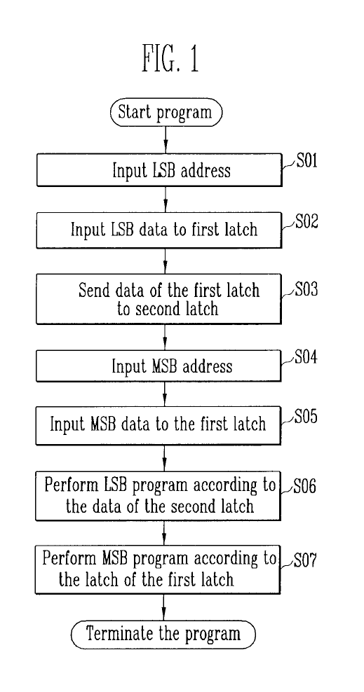

FIG. 1 is a flowchart illustrating a programming method for a nonvolatile memory device according to an exemplary embodiment of this disclosure.

When a programming process is started, an address for LSB programming is inputted in response to a program command at step S01. LSB data is inputted to the first latch of a page buffer at step S02. The LSB data inputted to the first latch is sent to the second latch of the page buffer at step S03. An address for MSB programming is inputted in response to the program command at step S04. MSB data is inputted to the first latch at step S05. Consequently, the MSB data is stored in the first latch of the page buffer, and the LSB data is stored in the second latch thereof.

An LSB programming operation is performed on selected memory cells using the LSB data stored in the second latch at step S06. For example, a case where a memory cell becomes an erase state, a first programming state, a second programming state, or a third programming state according to a level of the threshold voltage of the memory cell is described. Here, the LSB programming operation is performed to raise all the threshold voltages of memory cells to be programmed with the second and third programming states up to a target voltage of the second programming state.

When all the threshold voltages of the memory cells to be programmed with the second and third programming states reach the target voltage of the second programming state, the LSB programming is terminated. Next, an MSB programming operation is performed on the selected memory cells using the MSB data stored in the first latch at step S07. More particularly, the MSB programming operation is performed until all the threshold voltages of memory cells to be programmed with the first and third programming states reach the target voltage.

When all the threshold voltages of the selected memory cells reach the target voltage, all the programming operations are terminated.

FIG. 2 is a schematic block diagram of a nonvolatile memory device illustrating the programming method according to this disclosure.

The programming method described with reference to FIG. 1 is described below with reference to the schematic block diagram of the nonvolatile memory device.

Referring to FIG. 2, the nonvolatile memory device includes a memory cell array 100 for storing data, a page buffer PB for storing data to be programmed and outputting a programming operating voltage according to the stored data to be programmed, and an I/O circuit unit 110 for providing a data I/O path to the page buffer PB for the data I/O of the memory cell array 100.

It is to be noted that only one page buffer PB and only a first latch L1 and a second latch L2, from among a plurality of circuits constituting the page buffer PB, are shown in order to simply describe the programming method according to this disclosure.

The programming method is described below in detail.

An address including an LSB address is inputted. LSB data outputted from the I/O circuit unit 110 is inputted to the first latch L1 in response to an input signal IO (INPUT). The LSB data inputted to the first latch L1 is sent to the second latch L2 (TRAN). Next, an address including an MSB address is inputted. MSB data outputted from the I/O circuit unit 110 is inputted to the first latch L1 in response to the input signal IC (INPUT). Accordingly, both the MSB data and the LSB data are stored in the page buffer PB.

LSB programming is performed on selected memory cells included in the memory cell array 100 using the LSB data stored in the second latch L2 (LSG PGM). After the LSB programming is completed, MSB programming is performed on the selected memory cells of the memory cell array 100 using the MSB data stored in the first latch L1.

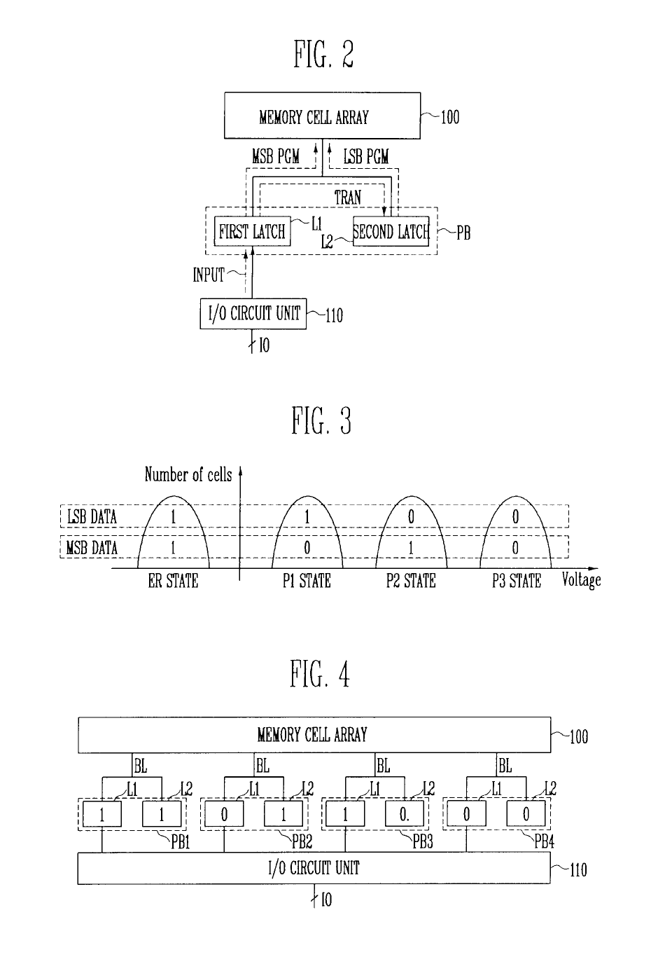

FIG. 3 is a diagram illustrating the states of memory cells according to threshold voltages, and FIG. 4 is a block diagram illustrating a programming method for a nonvolatile memory device according to an exemplary embodiment of this disclosure.

Referring to FIG. 3, the memory cells are classified into different states according to their threshold voltages. For example, memory cells having negative (−) threshold voltages are in an erase state ER STATE. Memory cells having positive (+) threshold voltages at the lowest level are in a first program state P1 STATE. Memory cells having threshold voltages higher than the first program state are in a second program state P2 STATE. Memory cells having threshold voltages higher than the second program state are in a third program state P3 STATE.

If LSB data LSB DATA is “1” and MSB data MSB DATA is “1”, it may be defined as the erase state ER STATE. According to the same data sequence, “10” may be defined as the first program state P1 STATE, “01” may be defined as the second program state P2 STATE, and “00” may be defined as the third program state P3 STATE.

A method of programming memory cells with different states is described below with reference to FIG. 4. It is to be noted that only four page buffers PB1 to PB4 are shown in order to program the memory cells with the four states (ER STATE and P1 to P3 STATES of FIG. 3).

Referring to FIG. 4, the nonvolatile memory device includes a memory cell array 100 for storing data, the first to fourth page buffers PB1 to PB4 for storing data to be programmed and outputting a programming operating voltage on the basis of the stored data to be programmed, and an I/O circuit unit 110 for inputting the data to be programmed to the first to fourth page buffers PB1 to PB4 or outputting the data.

For example, a case where data “11” for maintaining a memory cell to the erase state ER STATE is inputted to the first page buffer PB1 and any one of data “01” for programming memory cells with the first programming state P1 STATE, data “10” for programming the memory cells with the second programming state P2 STATE, and data “00” for programming the memory cells with the third programming state P3 STATE is inputted to the second to fourth page buffers PB2 to PB4 is described below.

When a programming process is started, LSB data outputted from the I/O circuit unit 110 is inputted to the first latches L1 of the first to fourth page buffers PB1 to PB4. More particularly, data “1” is inputted to the first latches L1 of the first and second page buffers PB1 and PB2, and data “0” is inputted to the first latches L1 of the third and fourth page buffers PB3 and PB4.

The LSB data stored in the first latches L1 of the first to fourth page buffers PB1 to PB4 are sent to the second latches L2 of the first to fourth page buffers PB1 to PB4. Accordingly, the same data as stored in the first latches L1 of the first to fourth page buffers PB1 to PB4 are stored in the second latches L2 of the first to fourth page buffers PB1 to PB4.

Next, MSB data outputted from the I/O circuit unit 110 is inputted to all the first latches L1 of the first to fourth page buffers PB1 to PB4. Accordingly, both the MSB data and the LSB data are stored in the first to fourth page buffers PB1 to PB4. More particularly, data “1” (MSB data) is stored in the first latch L1 of the first page buffer PB1, data “1” (LSB data) is stored in the second latch L2 of the first page buffer PB1. Data “0” (MSB data) is stored in the first latch L1 of the second page buffer PB2, and data “1” (LSB data) is stored in the second latch L2 of the second page buffer PB2. Data “1” (MSB data) is stored in the first latch L1 of the third page buffer PB3, and data “0” (LSB data) is stored in the second latch L2 of the third page buffer PB3. Data “0” (MSB data) is stored in the first latch L1 of the fourth page buffer PB4, and data “0” (LSB data) is stored in the second latch L2 of the fourth page buffer PB4.

An LSB programming operation is performed on selected memory cells included in the memory cell array 100 on the basis of the LSB data stored in the second latches L2 of the first to fourth page buffers PB1 to PB4.

More particularly, a bit line BL is discharged or is precharged to a program-inhibition voltage on the basis of LSB data stored in the second latch L2. For example, in case where the LSB data stored in the second latch L2 is “1”, the bit line BL is precharged to a program-inhibition voltage (e.g., Vcc) level. Meanwhile, in case where the LSB data stored in the second latch L2 is “0”, the bit line BL is discharged (e.g., Vss). That is, when the LSB programming operation is performed, the threshold voltages of memory cells coupled to the first and second page buffers PB1 and PB2 maintain the erase state (ER STATE of FIG. 3), and the threshold voltages of memory cells coupled to the third and fourth page buffers PB3 and PB4 are raised. The LSB programming operation is performed until all the threshold voltages of memory cells coupled to the third and fourth page buffers PB3 and PB4 reach a second target voltage (that is, a target voltage of the second program state P2 STATE). During the LSB programming operation, an LSB programming verification operation is performed using the second latch L2.

After the LSB programming is completed, the memory cells coupled to the first and second page buffers PB1 and PB2 maintain the erase state ER STATE, and the memory cells coupled to the third and fourth page buffers PB3 and PB4 become the second programming state P2 STATE.

Next, an MSB programming operation is performed. The MSB programming operation is performed on the basis of the MSB data stored in the first latches L1 of the first to fourth page buffers PB1 to PB4.

More particularly, the bit line BL is discharged or is precharged to a program-inhibition voltage on the basis of the MSB data stored in the first latch L1. For example, in case where the MSB data stored in the first latch L1 is “1”, the bit line BL is precharged to a program-inhibition voltage (e.g., Vcc) level. Meanwhile, in case where the MSB data stored in the first latch L1 is “0”, the bit line BL is discharged (e.g., Vss). That is, when the MSB programming operation is performed, the memory cells coupled to the first and third page buffers PB1 and PB2 maintains the state at the time of the LSB programming operation, and the memory cells coupled to the second and fourth page buffers PB2 and PB4 are programmed so that threshold voltages thereof reach respective target voltages.

More particularly, in the MSB programming operation, the memory cell coupled to the first page buffer PB1 maintains the erase state ER STATE, and the memory cell coupled to the third page buffer PV3 maintains the second program state P2 STATE. In the MSB programming operation, the memory cell coupled to the second page buffer PB2 is programmed so that a threshold voltage thereof reaches a first target voltage (that is, a target voltage of the first program state P1 STATE), and the memory cell coupled to the fourth page buffer PB4 is programmed until a threshold voltage thereof reaches a third target voltage (that is, a target voltage of the third program state P3 STATE). During the MSB programming operation, an MSB programming verification operation is performed using the first latch L1.

When all the threshold voltages of the memory cells coupled to the second and fourth page buffers PB2 and PB4 reach the target voltages of the first programming state P1 STATE and the third programming state P3 STATE, the entire programming operation is terminated.

As described above, in this disclosure, a programming operation for raising the threshold voltages of memory cells to be programmed with the second or third program state P2 STATE or P3 STATE to a temporary voltage lower than a target voltage is not performed. Accordingly, the time that it takes to perform the entire programming operation can be reduced.

In accordance with this disclosure, in a programming operation, LSB and MSB programming operations are performed in the state in which both LSB data and MSB data have been inputted to the page buffers. Accordingly, the time that it takes to perform the entire programming operation can be reduced.

What is claimed is:

1. A programming method of a nonvolatile memory device, comprising:
inputting least significant bit (LSB) data and most significant bit (MSB) data to different latches of a page buffer; and
performing sequentially an LSB programming operation and an MSB programming operation on the basis of the LSB data and the MSB data.

2. The programming method of claim 1, wherein the programming operation comprises performing a first programming operation and a first verification operation on the basis of the LSB data and then performing a second programming operation and a second verification operation on the basis of the MSB data.

3. The programming method of claim 1, wherein the LSB programming operation and the MSB programming operation are performed until threshold voltages of selected memory cells reach a target voltage.

4. The programming method of claim 1, wherein the LSB data and the MSB data are in the state in which the LSB data and the MSB data have been inputted to the page buffer.

5. A programming method of a nonvolatile memory device, comprising:
inputting MSB data to a first latch of a page buffer and LSB data to a second latch of the page buffer;
performing an LSB programming operation on selected memory cells using the LSB data; and
performing an MSB programming operation on the selected memory cells using the MSB data.

6. The programming method of claim 5, wherein inputting the LSB data and an MSB data comprises:
inputting the LSB data to the first latch;
sending the LSB data of the first latch to the second latch; and
inputting the MSB data to the first latch.

7. The programming method of claim 5, wherein the LSB programming operation is performed to program the selected memory cells on the basis of the LSB data stored in the second latch.

8. The programming method of claim 5, wherein the MSB programming operation is performed to program the selected memory cells on the basis of the MSB data stored in the first latch.

9. A programming method of a nonvolatile memory device comprising a page buffer including first and second latches, the programming method comprising:
inputting LSB data to the first latch;
sending the LSB data of the first latch to the second latch;
inputting MSB data to the first latch;
performing an LSB programming operation until threshold voltages of selected memory cells reach a second target voltage using the LSB data of the second latch; and
performing an MSB programming operation until threshold voltages of the selected memory cells reach one of a first target voltage and a third target voltage using the MSB data of the first latch.

10. The program method of claim 9, wherein:
the first target voltage is lower than the second target voltage, and the second target voltage is lower than the third target voltage.

11. The programming method of claim 9, wherein unselected memory cells maintain an erase state in the LSB programming operation.

12. The program method of claim 9, wherein the LSB programming operation is performed such that memory cells to be programmed to have threshold voltages equal to the third target voltage reach the second target voltage.

13. The programming method of claim 9, wherein the MSB programming operation is performed until threshold voltages of memory cells, selected from among memory cells of an erase state, reach the first target voltage and until threshold voltages of memory cells, selected from among memory cells programmed to have threshold voltages equal to the second target voltage reach the third target voltage.

14. The programming method of claim 9, wherein during the LSB programming operation, an LSB programming verification operation is performed using the second latch.

15. The programming method of claim 9, wherein during the MSB programming operation, an MSB programming verification operation is performed using the first latch.
